(19) United States
(12) Patent Application Publication
(10) Pub. No.: US 2026/0190718 A1
(43) Pub. Date: Jul. 2, 2026

(54) DISPLAY DEVICE

(71) Applicant: LG Display Co., Ltd., Seoul (KR)

(72) Inventor: Juyeon WON, Gimpo-si (KR)

(73) Assignee: LG Display Co., Ltd., Seoul (KR)

(21) Appl. No.: 19/436,522

(22) Filed: Dec. 30, 2025

(30) Foreign Application Priority Data
Dec. 31, 2024 (KR) 10-2024-0202056

(51) Int. Cl. H10K 59/131; H10K 59/122; H10K 59/124; H10K 59/80; H10K 59/88

(52) U.S. Cl. CPC H10K 59/131; H10K 59/122; H10K 59/124; H10K 59/80521; H10K 59/8722; H10K 59/873; H10K 59/88

(57) ABSTRACT

A display device includes a substrate having a display area and a non-display area, a plurality of first link lines and a plurality of second link lines disposed over the substrate in the non-display area, and a planarization layer extending from the display area to the non-display area. An adhesive layer is disposed over the planarization layer, an encapsulation substrate is disposed on the adhesive layer. A circuit part having a driving IC is positioned within the adhesive layer in the non display area. A first connection part electrically connects the plurality of first link lines to the circuit part, and a second connection part electrically connects the plurality of second link lines to the circuit part. This arrangement reduces the number of separate components and associated processing steps while supporting reliable electrical connection within the encapsulated structure.

### CROSS-REFERENCE TO RELATED APPLICATIONS

This application claims the priority of Korean Patent Application No. 10-2024-0202056 filed on Dec. 31, 2024, in the Korean Intellectual Property Office, the disclosure of which is incorporated herein by reference.

### BACKGROUND

### Technical Field

The present disclosure relates to a display device.

### Description of the Related Art

Currently, as it enters a full-fledged information era, the field of display devices that visually display electrical information signals is rapidly developing, and research is being conducted to develop characteristics such as thinning, weight reduction, and low power consumption for various display devices.

Representative display devices include a liquid crystal display (LCD), an electro-wetting display (EWD), and an organic light emitting display (OLED).

Among them, the electroluminescent display device including an organic light emitting display device is a self-emitting display device and does not require a separate light source unlike a liquid crystal display device, and thus may be manufactured to have a light weight and a small thickness. In addition, the electroluminescent display device is advantageous not only in terms of power consumption due to low voltage driving, but also in terms of color reproduction, response speed, viewing angle, and contrast ratio, so that it is expected to be used in various fields.

The electroluminescent display device receives various signals such as a driving signal and a data signal through a printed circuit board to display an image. Currently, as the source printed circuit board is manufactured separately from the display panel and attached to the display panel, there is a disadvantage in that the number of components and the assembly process are complicated. In addition, manufacturing costs may increase and productivity may decrease due to a plurality of components and process steps.

### BRIEF SUMMARY

The disclosed display device places the circuit part, including the driving IC, inside the encapsulation structure, specifically within the adhesive layer of the non display area. This configuration removes the need for an external source PCB and the associated pad region, which simplifies the component arrangement and assembly process, allows narrower bezel regions, and improves resistance to moisture by permitting the encapsulation structure to cover a larger area. Electrical connection to the embedded circuit part is achieved through a layered arrangement that includes first and second link lines, contact holes, contact electrodes, and anisotropic conductive connection parts, enabling dense signal routing within the non display region while avoiding exposed pad terminals.

Additional structural features contribute to electrical and environmental stability. A dummy bank is positioned between contact electrodes to enhance insulation, and a trench separates the planarization layer into inner and outer portions to interrupt potential moisture paths. An optional insulating layer located above the adhesive layer prevents unintended electrical contact between the circuit part and the encapsulation or reinforcing layers.

The encapsulation arrangement includes a multilayer sealing member composed of a first adhesive layer, a barrier layer, and a second adhesive layer, which supports the use of a thicker reinforcing substrate while limiting warpage and maintaining structural rigidity. The first adhesive layer can contain metal particles that assist with heat dissipation and hygroscopic inorganic fillers that reduce moisture permeation. Collectively, these structural arrangements support a highly integrated and reliable display module that differs significantly from arrangements that rely on external PCBs for driver mounting.

Various embodiments of the present disclosure provide a display device in which components and processes are simplified.

Various embodiments of the present disclosure provide a display device capable of improving reliability against moisture penetration.

Technical benefits of the present disclosure are not limited to the above-mentioned benefits, and other benefits, which are not mentioned above, can be clearly understood by those skilled in the art from the following descriptions.

A display device according to an exemplary embodiment of the present disclosure may include a substrate including a display area and a non-display area outside the display area, a plurality of first link lines and a plurality of second link lines disposed over the substrate in the non-display area and separated from each other, a planarization layer extending from the display area to the non-display area, an adhesive layer disposed over the planarization layer, an encapsulation substrate disposed on the adhesive layer, a circuit part disposed within the adhesive layer in the non-display area and having a driving IC disposed therein, a first connection part disposed between the plurality of first link lines and the circuit part, to electrically connect the plurality of first link lines with the circuit part, and a second connection part disposed between the plurality of second link lines and the circuit part, to electrically connect the plurality of second link lines with the circuit part.

A display device according to another exemplary embodiment of the present disclosure may include a substrate including a display area and a non-display area outside the display area, a plurality of first link lines and a plurality of second link lines disposed on the substrate in the non-display area and separated from each other, a planarization layer extending from the display area to the non-display area, a sealing member disposed on the planarization layer and including a first adhesive layer and a second adhesive layer and a barrier layer disposed between the first adhesive layer and the second adhesive layer, a reinforcing substrate disposed on the second adhesive layer, a circuit part disposed in the first adhesive layer in the non-display area and having a driving IC disposed therein, and a circuit part disposed between the plurality of first link lines and the plurality of second link lines and the circuit part, and electrically connecting the plurality of first link lines and the first circuit part.

Other detailed matters of the embodiments are included in the detailed description and the drawings.

According to the present disclosure, a circuit part such as a source printed circuit board required for driving a display panel is formed within an encapsulation structure, thereby simplifying components and processes. Accordingly, it provides the effect of improving process efficiency and reducing costs. Further, the reliability of the moisture barrier performance may be improved by expanding the design area of the encapsulation structure, and thus the reliability of the display device may be also improved.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:
FIG. 1 is a block diagram of a display device according to an embodiment of the present disclosure.

FIG. 2 is a circuit diagram of a sub-pixel of the display device of FIG. 1.

FIG. 3 is a plan view of a display device according to an embodiment of the present disclosure.

FIG. 4 is a cross-sectional view of one sub-pixel.

FIG. 5 is a cross-sectional view taken along the line I-I′ of FIG. 3.

FIG. 6 is an enlarged plan view of part A of FIG. 5.

FIG. 7 is another plan view showing an enlarged part A of FIG. 5.

FIG. 8 is a cross-sectional view of a display device according to another embodiment of the present disclosure.

FIG. 9 is a cross-sectional view of a display device according to still another embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The terms “coupled” and “in contact” should be interpreted in the same manner.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

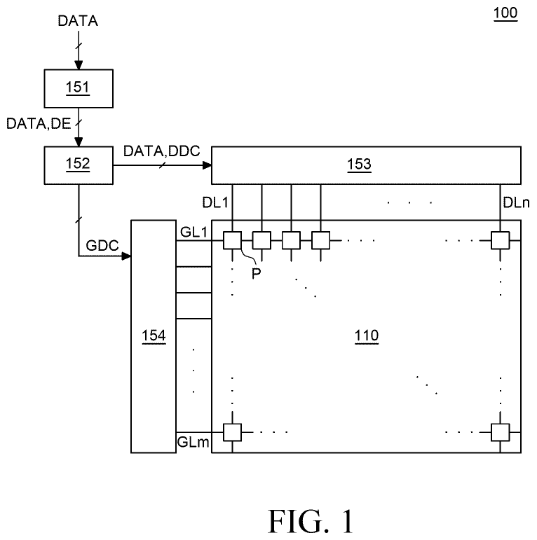

FIG. 1 is a block diagram of a display device according to an embodiment of the present disclosure.

Referring to FIG. 1, a display device 100 according to an embodiment of the present disclosure may include an image processor 151, a timing controller 152, a data driver 153, a gate driver 154, and a display panel 110.

The image processor 151 may output a data signal DATA, a data enable signal DE, and the like through a data signal DATA supplied from the outside.

The image processor 151 may output one or more of a vertical synchronization signal, a horizontal synchronization signal, and a clock signal in addition to the data enable signal DE.

The timing controller 152 is supplied with the data signal DATA together with the data enable signal DE or a driving signal including the vertical synchronization signal, the horizontal synchronization signal, and the clock signal from the image processor 151. The timing controller 152 may output a gate timing control signal GDC for controlling an operation timing of the gate driver 154 and a data timing control signal DDC for controlling an operation timing of the data driver 153 based on the driving signal.

Further, the data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 may output the data signal DATA through data lines DL1 to DLn.

Further, the gate driver 154 may output the gate signal while shifting a level of the gate voltage in response to the gate timing control signal GDC supplied from the timing controller 152. The gate driver 154 may output the gate signal through gate lines GL1 to GLm.

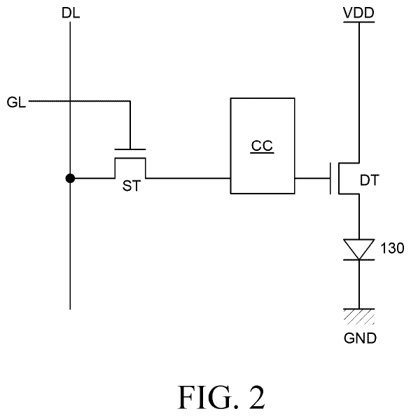

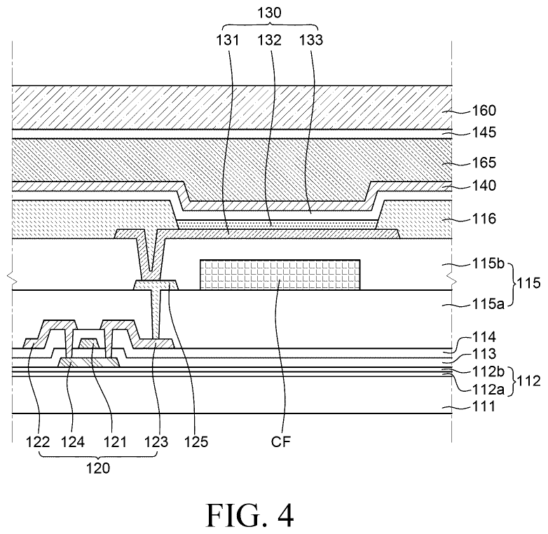

The display panel 110 may display an image while a sub-pixel P emits light in response to the data signal DATA and the gate signal supplied from the data driver 153 and the gate driver 154. A detailed structure of the sub-pixel P will be described with reference to FIGS. 2 and 4.

FIG. 2 is a circuit diagram of a sub-pixel of the display device of FIG. 1.

Referring to FIG. 2, a sub pixel of a display device according to an exemplary embodiment of the present disclosure may include a switching transistor ST, a driving transistor DT, a compensation circuit CC, and a light emitting element 130.

The light emitting element 130 may operate to emit light according to a driving current formed by the driving transistor DT.

The switching transistor ST may perform a switching operation such that a data signal supplied through a data line DL is stored in a capacitor as a data voltage in response to a gate signal supplied through a gate line GL.

In addition, the driving transistor DT may operate such that a constant driving current flows between a high potential power line VDD and a low potential power line GND in response to the data voltage stored in the capacitor.

The compensation circuit CC is a circuit for compensating for a threshold voltage, etc., of the driving transistor DT, and the compensation circuit CC may include one or more thin film transistors and capacitors. The configuration of the compensation circuit CC may vary depending on a compensation method.

For example, the sub pixel illustrated in FIG. 2 is configured by a 2T(transistor)1C(capacitor) including a switching transistor ST, a driving transistor DT, a capacitor, and a light emitting element 130. However, when the compensation circuit CC is added, the sub pixel may be configured in various forms, such as 3T1C, 4T2C, 5T2C, 6T1C, 6T2C, 7T1C, and 7T2C.

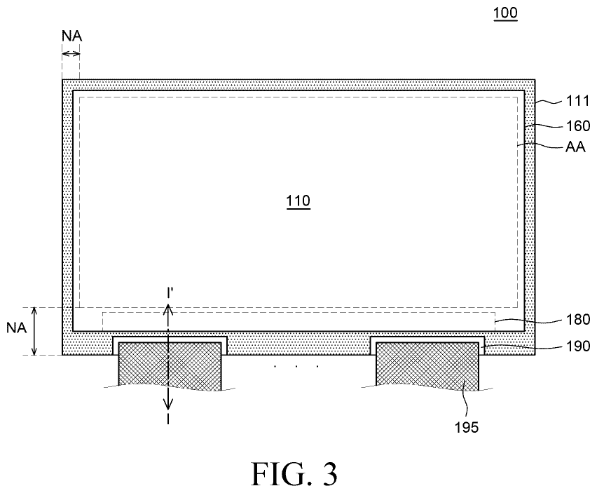

FIG. 3 is a plan view of a display device according to an embodiment of the present disclosure.

Referring to FIG. 3, the display device 100 according to the exemplary embodiment of the present disclosure may include a display panel 110 and a cable 195 connected to the display panel 110 through the connector 190.

The display panel 110 is a panel for displaying an image to a user.

The display panel 110 may include a display element configured to display images, a driving element configured to operate the display element, and wirings configured to transmit various signals to the display element and the driving element. The display element may be differently defined depending on the type of the display panel 110, and for example, when the display panel 110 is an organic light emitting display panel, the display element may be an organic light emitting element including an anode, an organic light emitting layer, and a cathode.

Hereinafter, even though it is assumed that the display panel 110 is an organic light emitting display panel, the display panel 110 is not limited to the organic light emitting display panel.

The display panel 110 may include a display area AA and a non-display area NA.

The display area AA is an area in which images are displayed on the display panel 110.

In the display area AA, a plurality of sub-pixels constituting a plurality of pixels and a circuit for driving the plurality of sub-pixels may be disposed. The plurality of sub-pixels is minimum units constituting the display area AA, and the display element may be disposed in each of the plurality of sub-pixels, and the plurality of sub-pixels may constitute a pixel. For example, the organic light emitting element including the anode, the organic emission layer, and the cathode may be disposed in each of the plurality of sub-pixels, but it is not limited thereto. Further, the circuit for driving the plurality of sub-pixels may include a driving element, a wiring, and the like. For example, the circuit may be formed of a thin film transistor, a storage capacitor, a gate line, a data line, or the like, but is not limited thereto.

The non-display area NA is an area where no image is displayed.

FIG. 3 illustrates that the non-display area NA encloses the display area AA having a rectangular shape. However, the shapes and arrangements of the display area AA and the non-display area NA are not limited to the example illustrated in FIG. 3.

In the non-display area NA, various wirings and circuits for driving the organic light emitting element of the display area AA may be disposed. For example, in the non-display area NA, a link line for transmitting signals to the plurality of sub-pixels and circuits of the display area AA or a driving IC such as a gate driver IC or a data driver IC may be disposed, but it is not limited thereto.

Conventionally, in order to drive the display panel, a circuit part such as a source printed circuit board is required. In the conventional module process, the source printed circuit board is attached to one end of the display panel and electrically connected to the pad part of the display panel through a driving IC. In this case, since the source printed circuit board is manufactured separately from the display panel and then attached to the display panel, there is a disadvantage in that the number of components and the assembly process are complicated. In addition, due to the multiple components and process steps, manufacturing costs may increase and productivity may decrease.

Accordingly, the display device 100 according to the exemplary embodiment of the present disclosure is characterized in that the circuit part 180 is disposed within the display panel 110 and provides various signals, such as driving signals and data signals received through the external cable 195, to the plurality of sub-pixels and circuits of the display area AA.

The circuit part 180 may serve the role of a conventional source printed circuit board, and a driving IC such as a data driver IC may be disposed therein.

Accordingly, components and processes can be simplified, thereby providing the effect of achieving process efficiency and reducing costs. Further, the reliability of the moisture barrier performance may be improved by expanding the design area of the encapsulation structure, and thus the reliability of the display device 100 may be improved.

For example, the circuit part 180 may be disposed in the non-display area NA of the display panel 110.

The circuit part 180 may be disposed between the substrate 111 and the encapsulation substrate 160. For example, the circuit part 180 may be disposed within the adhesive layer 165. For example, the circuit part 180 may be disposed within the adhesive layer 165 between the substrate 111 and an additional insulating layer.

The cable 195 is a component for supplying signals to the plurality of sub-pixels and the circuit of the display area AA through the circuit part 180, and may be electrically connected to the connector 190. The cable 195 is disposed at one end of the non-display area NA of the display panel 110 to supply a power voltage, a data voltage, and the like to the plurality of sub-pixels and the circuit of the display area AA. The cable 195 may be electrically connected to an external driving part of the set. For example, the cable 195 and the connector 190 may constitute an external contact structure for connection with an external driving part of the set.

The connector 190 may be disposed above the substrate 111 in the non-display area NA that is not covered by the encapsulation substrate 160.

A plurality of connectors 190 and cables 195 may be provided, but the present disclosure is not limited thereto, and may be provided as one.

The cable 195 may correspond to the connector 190 one-to-one, but is not limited thereto.

The cable 195 may be inserted into and fastened to the connector 190, but is not limited thereto.

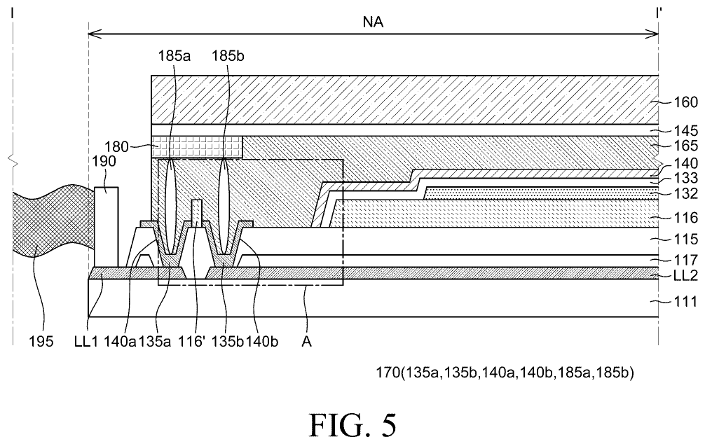

The connector 190, the cable 195, and the circuit part 180 will be described in more detail with reference to FIGS. 5 to 7.

FIG. 4 is a cross-sectional view of one sub-pixel.

FIG. 5 is a cross-sectional view taken along the line I-I′ of FIG. 3.

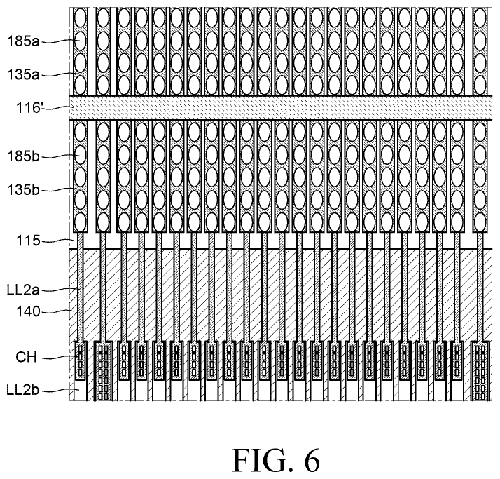

FIG. 6 is an enlarged plan view of part A of FIG. 5.

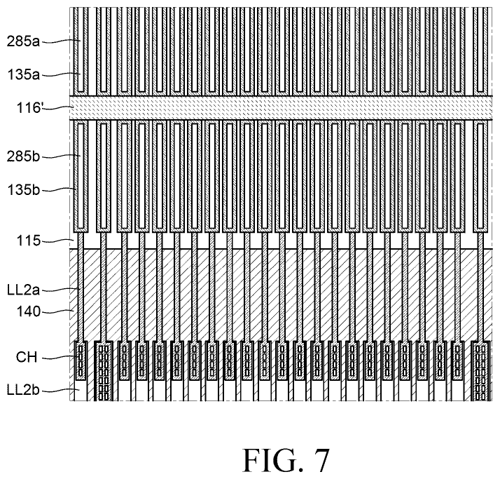

FIG. 7 is another plan view showing an enlarged part A of FIG. 5.

In FIG. 5, for the convenience of illustration, at least some of a buffer layer 112, a gate insulating layer 113, and an interlayer insulating layer 114 are illustrated as insulating layers 117.

In FIGS. 6 and 7, for the convenience of illustration, the configuration above the protective layer 140 is omitted. FIGS. 6 and 7 illustrate an example of a contact structure between the bonding structure 170 and the circuit part 180, but are not limited thereto and may be implemented in various forms.

Referring to FIGS. 4 to 7, in the display device 100 of FIG. 3 according to the exemplary embodiment of the present disclosure, the driving element 120 may be disposed on the substrate 111.

Further, the planarization layer 115 may be disposed over the driving element 120.

Further, the light emitting element 130 electrically connected to the driving element 120 may be disposed over the planarization layer 115, and the protective layer 140 may be disposed over the light emitting element 130.

The adhesive layer 165, the additional insulating layer 145, and the encapsulation substrate 160 may be sequentially disposed over the protective layer 140.

However, the display device 100 according to the exemplary embodiment of the present disclosure is not limited to such a stacked structure.

The substrate 111 may be a glass or plastic substrate. In the case of a plastic substrate, a polyimide-based or polycarbonate-based material may be used to have flexibility. In particular, polyimide is a material that can be applied to a high-temperature process and can be coated, so it is widely used as a plastic substrate.

A buffer layer 112 may be disposed on the substrate 111.

Meanwhile, although not illustrated, a light shielding layer may be disposed on the substrate 111 to block light introduced from a lower portion of the substrate 111.

The light shielding layer may be disposed on the substrate 111 at a position where the active layer 124 is to be formed. In particular, it is preferable that the size of the light shielding layer is slightly larger so as to completely cover the active layer 124.

The buffer layer 112 may be disposed on the entire surface of the substrate 111 on which the light shielding layer is formed.

The buffer layer 112 is a layer for protecting various electrodes and wirings from impurities such as alkali ions discharged from the substrate 111 or the underlying layers. The buffer layer 112 may have a multilayer structure including a first buffer layer 112a and a second buffer layer 112b, but is not limited thereto. For example, the buffer layer 112 may be made of silicon oxide (SiOx), silicon nitride (SiNx), or a multi-layer thereof.

The buffer layer 112 may delay diffusion of moisture and/or oxygen permeating the substrate 111. In addition, the buffer layer 112 may include a multi-buffer and/or an active buffer. The active buffer protects the active layer 124 made of the semiconductor of the driving element 120 and may perform a function of blocking various types of defects introduced from the substrate 111. The active buffer may be formed of amorphous silicon (a-Si) or the like.

Meanwhile, in the non-display area NA, various wirings and circuits for driving the light emitting element 130 of the display area AA may be disposed. For example, in the non-display area NA, the circuit part 180 may be disposed, which includes a plurality of link lines LL1 and LL2 for transmitting signals to the plurality of sub-pixels and circuits of the display area AA, as well as driving ICs such as a gate driver IC and a driving IC, but is not limited thereto.

For example, the first link line LL1 and the second link line LL2 may be disposed on the substrate 111 in the non-display area NA.

The first link line LL1 may be disposed at an edge of the lower non-display area NA. The second link line LL2 may be spaced apart from the first link line LL1 by a predetermined distance and disposed further inward than the first link line LL1.

For example, the second link line LL2 may be separated from the first link line LL1.

A plurality of first link lines LL1 and a plurality of second link lines LL2 may be provided. For example, the first link line LL1 and the second link line LL2 may be disposed in a number corresponding to the number of signal lines. For example, at a resolution of 1024×768, each of the first link line LL1 and the second link line LL2 may be disposed in 1024 units, corresponding to the number of horizontal pixels (horizontal resolutions).

For example, the first link line LL1 and the second link line LL2 may be formed of a conductive material which configures the light shielding layer and/or the driving element 120 of the display area AA, but are not limited thereto.

For example, the second link line LL2 includes a lower second link line LL2b and an upper second link line LL2a. The upper second link line LL2a may be electrically connected to the lower second link line LL2b through a contact hole CH (see FIG. 6 and FIG. 7). Further, for example, the lower second link line LL2b may be made of a material constituting the light shielding layer, and the upper second link line LL2a may be made of a material constituting the gate electrode, but is not limited thereto. In addition, the first link line LL1 may be formed of the same conductive material on the same layer as the upper second link line LL2a, but is not limited thereto.

In addition, the first link line LL1 and the second link line LL2 may be disposed in parallel in one direction, but are not limited thereto. The first link line LL1 and the second link line LL2 may be disposed in a zigzag shape, or may be disposed to be inclined at a predetermined angle. Further, each of the plurality of first link lines LL1 and the second link line LL2 may be disposed to be inclined at different angles.

The driving element 120 may include an active layer 124, a gate insulating layer 113, a gate electrode 121, an interlayer insulating layer 114, a source electrode 122, and a drain electrode 123. Further, the driving element 120 may be electrically connected to the light emitting element 130 through a connection electrode 125 to transmit a current or a signal to the light emitting element 130. In addition to the illustrated top gate structure, the driving element 120 may be applied in various ways, such as a bottom gate in which the gate electrode is located below the active layer and a coplanar structure in which the gate electrode, the source electrode, and the drain electrode are disposed on the same plane.

The active layer 124 may be positioned on the buffer layer 112. The active layer 124 may be made of polysilicon (p-Si), and in this case, a predetermined region may be doped with impurities. Further, the active layer 124 may be made of amorphous silicon (a-Si) and may be made of an organic semiconductor material such as pentacene. Further, the active layer 124 may be formed of an oxide semiconductor.

The gate insulating layer 113 may be positioned on the active layer 124. For example, the gate insulating layer 113 may be formed of an insulating inorganic material such as silicon oxide (SiOx) or silicon nitride (SiNx), or an insulating organic material.

The gate electrode 121 may be positioned on the gate insulating layer 113. For example, the gate electrode 121 may be made of various conductive materials, such as magnesium (Mg), aluminum (Al), nickel (Ni), chromium (Cr), molybdenum (Mo), tungsten (W), gold (Au), or an alloy thereof.

The interlayer insulating layer 114 may be positioned on the gate electrode 121. For example, the interlayer insulating layer 114 may be formed of an insulating material such as silicon oxide (SiOx) or silicon nitride (SiNx), or an insulating organic material.

A contact hole through which the source and drain regions are exposed may be formed by selective removal of the gate insulating layer 113 and the interlayer insulating layer 114. The source electrode 122 and the drain electrode 123 may be formed on the interlayer insulating layer 114 in a single layer or a multi-layered structure using an electrode material.

If necessary, an additional protective layer made of an inorganic insulating material may be formed to cover the source electrode 122 and the drain electrode 123.

The planarization layer 115 may be disposed over the driving element 120 configured as described above.

The planarization layer 115 may have a multilayer structure including at least two layers. For example, referring to FIG. 4, the planarization layer 115 may include a first planarization layer 115a and a second planarization layer 115b, but is not limited thereto.

For example, the first planarization layer 115a is disposed to cover the driving element 120 and may be disposed to expose a part of the source electrode 122 or the drain electrode 123 of the driving element 120.

The planarization layer 115 may be an overcoat layer, but is not limited thereto.

The connection electrode 125 for electrically connecting the driving element 120 and the light emitting element 130 may be disposed on the first planarization layer 115a. Although not illustrated in FIG. 4, various metal layers serving as wires/electrodes, such as data lines and signal lines, may be disposed on the first planarization layer 115a.

Further, a color filter CF may be disposed on the first planarization layer 115a. However, the present disclosure is not limited thereto. The color filter CF may be omitted depending on the type of the light emitting element 130.

The color filter CF of each sub-pixel may have any one of red, green, and blue. In addition, in the case of a sub-pixel in which white is implemented, the color filter CF may not be provided. The arrangement of red, green, and blue may be formed in various ways, and a black matrix capable of absorbing external light may be provided between the color filters CF.

In the case of the bottom emission type, the color filter CF may be located under the anode 131.

Further, the second planarization layer 115b may be disposed on the first planarization layer 115a and the connection electrode 125.

The second planarization layer 115b may be formed to expose a part of the connection electrode 125. Further, the drain electrode 123 of the driving element 120 and the anode 131 of the light emitting element 130 may be electrically connected by the connection electrode 125.

In this case, the light emitting element 130 may be configured such that the anode 131, a plurality of organic layers 132, and the cathode 133 are sequentially disposed. That is, the light emitting element 130 may include an anode 131 disposed on the planarization layer 115, an organic layer 132 disposed on the anode 131, and a cathode 133 disposed on the organic layer 132.

The display device 100 may be implemented in a top emission type or a bottom emission type. In the top emission type, a reflective layer made of an opaque conductive material having high reflectivity, for example, silver (Ag), aluminum (Al), gold (Au), molybdenum (Mo), tungsten (W), chromium (Cr), or an alloy thereof, may be added under the anode 131 so that light emitted from the organic layer 132 is reflected by the anode 131 and directed upward, that is, in the direction of the cathode 133 at the top. Conversely, in the case of the bottom emission type, the anode 131 may be made of only a transparent conductive material such as indium tin oxide (ITO), indium zinc oxide (IZO), indium gallium zinc oxide (IGZO). Hereinafter, the description will be made on the assumption that the display device 100 of the present disclosure is a bottom emission type. However, the present disclosure is not limited thereto.

A bank 116 may be formed on the planarization layer 115 in a region other than the emission region. That is, the bank 116 has a bank hole exposing the anode 131 corresponding to the emission area. The bank 116 may be made of an inorganic insulating material such as silicon nitride (SiNx) or silicon oxide (SiOx), or an organic insulating material such as benzocyclobutene (BCB), acrylic resin, or imide resin.

The organic layer 132 may be disposed on the anode 131 exposed by the bank 116. The organic layer 132 may include an emission layer, an electron injection layer, an electron transport layer, a hole transport layer, a hole injection layer, and the like.

The cathode 133 may be disposed on the organic layer 132.

In the case of the top emission type, the cathode 133 may include a transparent conductive material. For example, the cathode 133 may be formed of indium tin oxide (ITO), indium zinc oxide (IZO), indium gallium zinc oxide (IGZO), or the like. In the case of the bottom emission type, the cathode 133 may include any one of a group formed of a metal material such as gold (Au), silver (Ag), aluminum (Al), molybdenum (Mo), magnesium (Mg), palladium (Pd), copper (Cu) or an alloy thereof. Alternatively, the cathode 133 may be configured by laminating a layer made of a transparent conductive material such as indium tin oxide (ITO), indium zinc oxide (IZO), indium gallium zinc oxide (IGZO), and a layer made of a metal material such as gold (Au), silver (Ag) aluminum (Al), molybdenum (Mo), magnesium (Mg), palladium (Pd), copper (Cu), or an alloy thereof, but is not limited thereto.

Although not illustrated, a capping layer may be disposed on the cathode 133. The capping layer may be formed of a material having a high refractive index and a high light absorption rate to reduce diffused reflection of external light.

The protective layer 140 may be disposed on the light emitting element 130 configured as described above.

The protective layer 140 may be an inorganic layer, and in this case, may be made of silicon oxide (SiOx), silicon nitride (SiNx), or a multi-layer thereof.

Meanwhile, at least some layers of the buffer layer 112, the gate insulating layer 113, and the interlayer insulating layer 114, i.e., the insulating layer 117, may extend to the non-display area NA.

Further, the planarization layer 115 may extend to the non-display area NA.

The insulating layer 117 and the planarization layer 115 extending to the non-display area NA may have certain portions selectively removed, forming a first contact hole 140a and a second contact hole 140b that expose portions of the first link line LL1 and the second link line LL2.

The first contact hole 140a and the second contact hole 140b may be disposed so as to correspond to the first link line LL1 and the second link line LL2, respectively.

In addition, outer portions of the insulating layer 117 and the planarization layer 115 may be selectively removed to expose another portion of the first link line LL1.

In this case, the exposed another portion of the first link line LL1 may be electrically connected to the connector 190. The connector 190 may be disposed above the substrate 111 in the non-display area NA that is not covered by the encapsulation substrate 160 to be electrically connected to the exposed another portion of the first link line LL1. Further, the cable 195 may be disposed at one end of the non-display area NA of the display panel 110 and electrically connected to the connector 190.

Further, a first contact electrode 135a and a second contact electrode 135b may be disposed over the planarization layer 115 in the non-display area NA.

A plurality of first contact electrodes 135a and a plurality of second contact electrodes 135b may be provided.

The first contact electrode 135a may be electrically connected to the first link line LL1 through the first contact hole 140a, and the second contact electrode 135b may be electrically connected to the second link line LL2 through the second contact hole 140b.

The first contact electrode 135a and the second contact electrode 135b may correspond to the first link line LL1 and the second link line LL2 one-to-one, respectively, but are not limited thereto.

For example, the first contact electrode 135a and the second contact electrode 135b may be disposed in parallel in one direction, but are not limited thereto.

For example, the first contact electrode 135a and the second contact electrode 135b may overlap the first link line LL1 and the second link line LL2, respectively.

For example, the first contact electrode 135a and the second contact electrode 135b may be formed of a conductive material constituting the anode 131, but are not limited thereto.

Further, the bank 116 may extend to the non-display area NA.

A part of the bank 116 may constitute an island-shaped dummy bank 116′ at an edge of the non-display area NA. The dummy bank 116′ may be disposed between the first contact electrode 135a and the second contact electrode 135b. The dummy bank 116′ may be disposed spaced apart from another part (e.g., a remaining part) of the bank 116.

The first contact electrode 135a and the second contact electrode 135b may be separated from each other through the dummy bank 116′.

For example, the dummy bank 116′ may be disposed in another direction perpendicular to one direction.

The dummy bank 116′ may be disposed between the first contact electrode 135a and the second contact electrode 135b in a direction crossing the first contact electrode 135a and the second contact electrode 135b.

Meanwhile, in the non-display area NA, the organic layer 132 may be disposed on the bank 116.

The organic layer 132 extends to the non-display area NA, and its edges may be disposed inward of the edges of the bank 116, but is not limited thereto.

The cathode 133 may extend to the non-display area NA.

In the non-display area NA, the cathode 133 may be disposed on the organic layer 132.

The cathode 133 may extend to the non-display area NA to cover the organic layer 132 and the bank 116.

The protective layer 140 may extend to the non-display area NA.

The protective layer 140 may extend to the non-display area NA to cover the cathode 133.

For example, the protective layer 140 may be made of an inorganic insulating material.

The protective layer 140 may delay moisture permeation from the top and suppress defects caused by pressing or foreign particles.

The adhesive layer 165 and the encapsulation substrate 160 may be disposed over the protective layer 140.

However, the present disclosure is not limited thereto, and an encapsulation structure of a multilayer structure composed of a sealing member and a reinforcing substrate may be disposed on the protective layer 140.

Meanwhile, an embodiment of the present disclosure is characterized in that the additional insulating layer 145 is disposed between the adhesive layer 165 and the encapsulation substrate 160.

The adhesive layer 165 may be disposed between the protective layer 140 and the additional insulating layer 145.

For example, the adhesive layer 165 may serve to delay lateral moisture permeation.

For example, the adhesive layer 165 may further include a desiccant such as a getter in addition to isobutyl rubber resin. The desiccant may include calcium oxide.

The desiccant may be particles having hygroscopicity and absorb moisture and oxygen from the outside to minimize the penetration of moisture and oxygen into the display area AA.

The additional insulating layer 145 may be disposed on the adhesive layer 165.

The additional insulating layer 145 may be added to prevent a short circuit between the circuit part 180 and the encapsulation substrate 160.

The encapsulation substrate 160 may be disposed on the additional insulating layer 145.

The encapsulation substrate 160, together with the adhesive layer 165, may protect the light emitting element 130 from external moisture, oxygen, impact, and the like.

For example, the encapsulation substrate 160 may serve to prevent moisture permeation from the front.

For example, the encapsulation substrate 160 may be made of steel use stainless (SUS) or Invar, but is not limited thereto. At this time, Invar is one of the alloys consisting of nickel and iron, and has a very low coefficient of thermal expansion and is relatively stable against temperature changes.

Meanwhile, according to an embodiment of the present disclosure, the circuit part 180 is disposed within the display panel (110 in FIG. 3).

The circuit part 180 may serve the role of a conventional source printed circuit board, and a driving IC such as a data driver IC may be disposed therein.

For example, the circuit part 180 may be disposed within the non-display area NA of the display panel 110. The circuit part 180 may be disposed at the edge of the non-display area NA.

The circuit part 180 may be disposed between the substrate 111 and the encapsulation substrate 160. For example, the circuit part 180 may be disposed within the adhesive layer 165. For example, the circuit part 180 may be disposed within the adhesive layer 165 between the substrate 111 and the additional insulating layer 145. In this case, since the design area of the encapsulation structure may be expanded, moisture permeation reliability may be improved. That is, conventionally, the pad part was not covered by the encapsulation structure in order to connect the source printed circuit board to the pad part, but according to an embodiment of the present disclosure, the circuit part 180 may be disposed within the encapsulation structure and electrically connected to the bonding structure 170 without a pad part, thereby allowing the encapsulation structure to be expanded. As the encapsulation structure is expanded, moisture permeation is delayed, so reliability may be improved.

The circuit part 180 may be electrically connected to the bonding structure 170.

For example, the bonding structure 170 may electrically connect the circuit part 180 and the first link line LL1 and the second link line LL2.

The bonding structure 170 may include, for example, a first contact hole 140a and a second contact hole 140b, a first contact electrode 135a and a second contact electrode 135b, and first connection parts 185a and 285a and second connection parts 185b and 285b.

For example, the input unit of the circuit part 180 and the first contact electrode 135a may be electrically connected through the first connection parts 185a and 285a. For example, the input unit may include a plurality of input terminals, but is not limited thereto.

For example, the output unit of the circuit part 180 and the second contact electrode 135b may be electrically connected through the second connection parts 185b and 285b. For example, the output unit may include a plurality of output terminals, but is not limited thereto.

For example, the first connection parts 185a and 285a and the second connection parts 185b and 285b may be formed of a conductor such as an anisotropic conductive film (ACF). That is, for example, the first connection parts 185a and 285a and the second connection parts 185b and 285b may be configured by the conductive balls as in FIG. 6 or the conductive bars as in FIG. 7, but are not limited thereto.

Meanwhile, in the present disclosure, in order to minimize the penetration of moisture, the planarization layer of the pad bonding portion may be formed in an island shape, which will be described in detail with reference to the drawings.

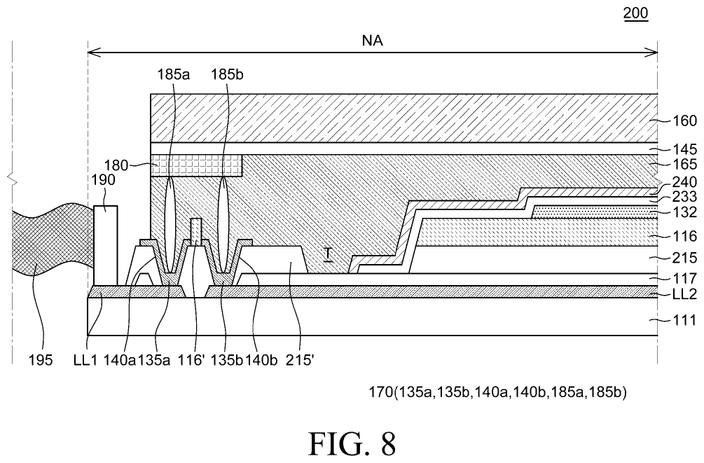

FIG. 8 is a cross-sectional view of a display device according to another embodiment of the present disclosure.

In another embodiment of FIG. 8, a configuration of the planarization layers 215 and 215′ is different from that of the embodiment of FIGS. 1 to 7 described above, and other configurations are substantially the same, so that a redundant description will be omitted. The same components will be denoted by the same reference numerals. Hereinafter, description of the same reference numerals may refer to FIG. 1 through FIG. 7.

In FIG. 8, for the convenience of illustration, at least some of the buffer layer 112, the gate insulating layer 113, and the interlayer insulating layer 114 are illustrated as insulating layers 117.

Referring to FIG. 8, in the display device 200 according to another exemplary embodiment of the present disclosure, a driving element (120 in FIG. 4) may be disposed over the substrate 111.

Further, a planarization layer 215 may be disposed over the driving element 120.

Further, a light emitting element (130 in FIG. 4) which is electrically connected to the driving element 120 may be disposed over the planarization layer 215, and a protective layer 240 may be disposed over the light emitting element 130.

The adhesive layer 165, the additional insulating layer 145, and the encapsulation substrate 160 may be sequentially disposed over the protective layer 240.

However, the display device 200 according to another exemplary embodiment of the present disclosure is not limited to such a stacked structure.

For example, the first link line LL1 and the second link line LL2 may be disposed over the substrate 111 in the non-display area NA.

The first link line LL1 may be disposed at an edge of the lower non-display area NA. The second link line LL2 may be spaced apart from the first link line LL1 by a predetermined distance and disposed further inward than the first link line LL1.

Further, at least some of the buffer layer (112 in FIG. 4), the gate insulating layer (113 in FIG. 4), and the interlayer insulating layer (114 in FIG. 4), that is, the insulating layer 117, may extend to the non-display area NA.

Further, the planarization layer 215 may extend to the non-display area NA.

The display device 200 according to another exemplary embodiment of the present disclosure is characterized in that the planarization layer 215 extending to the non-display area NA is separated from the planarization layer 215′ of the bonding structure 170.

In addition, the display device 200 according to another exemplary embodiment of the present disclosure is characterized in that the trench T is provided in the non-display area NA to secure reliability such as prevention of moisture permeation.

Meanwhile, for convenience of illustration, the planarization layer 215 may be referred to as an inner planarization layer 215, and the planarization layer 215′ of the bonding structure 170 may be referred to as an outer planarization layer 215′. In this case, the planarization layers 215 and 215′ according to another embodiment of the present disclosure may include the inner planarization layer 215 disposed inside the trench T with respect to the trench T, and the outer planarization layer 215′ disposed outside the trench T.

For example, the trenches T may be disposed side by side in one direction. For example, the one direction may be a direction parallel to the gate line. For example, the trench T may be disposed in parallel with the dummy bank 116′.

The inner planarization layer 215 and the outer planarization layer 215′ may be formed by the same process, but are not limited thereto, and may be formed by different processes.

As described above, the display device 200 according to another exemplary embodiment of the present disclosure may effectively block the penetration of moisture through the inner planarization layer 215 by separating and forming the inner planarization layer 215 and the outer planarization layer 215′ around the trench T.

Meanwhile, the bank 116 may extend to the non-display area NA.

For example, an edge of the bank 116 extending to the non-display area NA may be disposed inward compared to an edge of the inner planarization layer 215, but is not limited thereto.

A part of the bank 116 may constitute an island-shaped dummy bank 116′ at an edge of the non-display area NA. The dummy bank 116′ may be disposed spaced apart from another part (e.g., a remaining part of the bank 116.

Further, in the non-display area NA, the organic layer 132 may be disposed on the bank 116.

The organic layer 132 extends to the non-display area NA, and its edge may be disposed inside compared to the edge of the bank 116, but is not limited thereto.

The cathode 233 may extend to the non-display area NA.

In the non-display area NA, the cathode 233 may be disposed on the organic layer 132.

The cathode 233 may extend to the non-display area NA to cover the organic layer 132, the bank 116, and the inner planarization layer 215. The cathode 233 may extend into the trench T so as to cover a part of the upper surface of the exposed insulating layer 117.

The cathode 233 may be in contact with an upper surface of the exposed insulating layer 117.

The cathode 233 may be spaced apart from the outer planarization layer 215′ by a predetermined distance.

The protective layer 240 may extend to the non-display area NA.

The protective layer 240 may extend to the non-display area NA to cover the cathode 233.

The protective layer 240 may extend into the trench T so as to cover a portion of the upper surface of the cathode 233 and the exposed insulating layer 117.

The protective layer 240 may be in contact with the upper surface of the exposed insulating layer 117.

The protective layer 240 may be spaced apart from the outer planarization layer 215′ by a predetermined distance.

The adhesive layer 165 and the encapsulation substrate 160 may be disposed over the protective layer 240.

Meanwhile, according to the present disclosure, an encapsulation structure of a multilayer structure composed of a sealing member and a reinforcing substrate may be disposed over the protective layer, which will be described in detail with reference to the drawings.

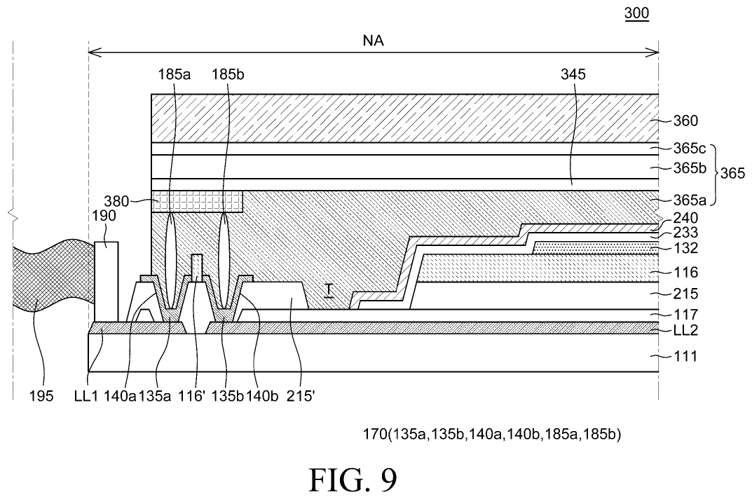

FIG. 9 is a cross-sectional view of a display device according to still another embodiment of the present disclosure.

Another embodiment of FIG. 9 is substantially the same as the other embodiment of FIG. 8 except that an encapsulation structure of a multilayer structure composed of a sealing member 365 and a reinforcing substrate 360 is applied. Therefore, repeated descriptions of the identical components will be omitted. In addition, the same reference numerals will be used for the same components. Hereinafter, description of the same reference numerals may refer to FIGS. 1 to 8.

Referring to FIG. 9, in the display device 300 according to still another exemplary embodiment of the present disclosure, an encapsulation structure of a multilayer structure composed of a sealing member 365 and a reinforcing substrate 360 may be disposed over the protective layer 240.

A small-sized display panel used in a mobile device and a portable device has a small area of the display panel so that heat generation in an element is rapidly emitted and there is less problem of bonding. However, in a large-sized display panel used in a monitor, tablet, or television receiver, the area of the display panel is large, so that an encapsulation structure for an optimal heat dissipation effect and bonding force is required.

In addition, in order to ensure sufficient rigidity, the display device may further include a separate inner plate on the encapsulation substrate. In this case, it is necessary to secure a space for disposing a separate inner plate, and there is a problem in that there is a limitation in slimming and lightening of the display device due to the weight of the inner plate. In addition, there is a limitation in that a vertical space is generated by an air gap generated between the encapsulation substrate and the inner plate as much as the thickness of the adhesive tape disposed to adhere the encapsulation substrate and the inner plate, thereby deteriorating heat dissipation performance.

Accordingly, in still another embodiment of the present disclosure, it is possible to fix the reinforcing substrate 360 having a relatively large thickness while removing the separate inner plate, and it is characterized in that the encapsulation structure of the multilayer structure including a sealing member 365 which can prevent a process defect is applied.

For example, the sealing member 365 according to still another exemplary embodiment of the present disclosure may include a first adhesive layer 365a facing the substrate 111, a second adhesive layer 365c facing the reinforcing substrate 360, and a barrier layer 365b disposed between the first adhesive layer 365a and the second adhesive layer 365c.

In this case, each of the first adhesive layer 365a and the second adhesive layer 365c may be made of a polymer material having adhesiveness. For example, the first adhesive layer 365a may be made of any one of olefin-based, epoxy-based, and acrylate-based polymer materials. In addition, the second adhesive layer 365c may be made of any one of olefin-based, epoxy-based, acrylate-based, amine-based, phenol-based, and acid anhydride-based materials that do not contain a carboxyl group.

For heat dissipation of the substrate 111, at least the first adhesive layer 365a of the first and second adhesive layers 365a and 365c may be formed of a mixture including particles of an adhesive polymer material and a metal material. For example, the particles of the metal material may be powder made of nickel (Ni).

In this way, since the speed at which the driving heat generated in the substrate 111 is discharged through the sealing member 365 may be improved, the heat dissipation effect on the substrate 111 may be improved.

Further, in order to prevent moisture permeation, the first adhesive layer 365a may be formed of a mixture further including a hygroscopic inorganic filler. The hygroscopic inorganic filler may be at least one of barium oxide (BaO), calcium oxide (CaO), and magnesium oxide (MgO).

In addition, since the first adhesive layer 365a and the second adhesive layer 365c are formed in a multi-layered structure, there is an advantage in that the reliability to reduce the warpage phenomenon in which the display panel is bent may also be improved.

The barrier layer 365b may be formed of any one of a metal material and an inorganic insulating material. That is, the barrier layer 365b may include a metal material such as Al, Cu, Sn, Ag, Fe, Zn and the like. In another example, the barrier layer 365b may be formed of a thin film of an inorganic insulating material such as SiOx and SiONx.

Since the sealing member 365 according to still another embodiment of the present disclosure includes the first adhesive layer 365a and the second adhesive layer 365c separated by the barrier layer 365b, it may be implemented to have a thickness approximately twice as thick as the adhesive material of the single layer without a process defect. Accordingly, since the reinforcing substrate 360 fixed by the sealing member 365 may be provided with a thick thickness, there is an advantage in that the increase in rigidity and the improvement of the heat dissipation effect may be easily realized.

For example, the reinforcing substrate 360 may be made of any one of glass, metal, and plastic polymers. For example, the reinforcing substrate 360 may be made of a metal material including components of Al, Cu, Sn, Ag, Fe, or Zn.

Meanwhile, in still another embodiment of the present disclosure, an additional insulating layer 345 may be disposed between the first adhesive layer 365a and the barrier layer 365b.

The additional insulating layer 345 may be added to prevent a short circuit between the circuit part 380 and the barrier layer 365b.

The circuit part 380 according to still another embodiment of the present disclosure may be disposed between the substrate 111 and the reinforcing substrate 360. For example, the circuit part 380 may be disposed in the first adhesive layer 365a. For example, the circuit part 380 may be disposed in the first adhesive layer 365a between the substrate 111 and the additional insulating layer 345.

The exemplary embodiments of the present disclosure can also be described as follows:

A display device according to an exemplary embodiment of the present disclosure may include a substrate including a display area and a non-display area outside the display area, a plurality of first link lines and a plurality of second link lines disposed over the substrate in the non-display area and separated from each other, a planarization layer extending from the display area to the non-display area, an adhesive layer disposed over the planarization layer, an encapsulation substrate disposed on the adhesive layer, a circuit part disposed within the adhesive layer in the non-display area and having a driving IC disposed therein, a first connection part disposed between the plurality of first link lines and the circuit part, to electrically connect the plurality of first link lines with the circuit part, and a second connection part disposed between the plurality of second link lines and the circuit part, to electrically connect the plurality of second link lines with the circuit part.

The display device may further include a first contact hole and a second contact hole which are formed by removing a portion of the planarization layer of the non-display area to expose a portion of upper surfaces of the first link line and the second link line.

The display device may further include a first contact electrode disposed over the planarization layer and electrically connected to the first link line through the first contact hole, and a second contact electrode disposed over the planarization layer and electrically connected to the second link line through the second contact hole, the first contact electrode and the second contact electrode may be electrically connected to the first connection part and the second connection part, respectively.

The first contact electrode and the second contact electrode are provided in plural, and the plurality of first contact electrodes and the plurality of second contact electrodes may respectively correspond in a one-to-one manner with the plurality of first link lines and the plurality of second link lines.

The first contact electrode and the second contact electrode overlap the first link line and the second link line, respectively, and the first contact electrode and the second contact electrode may be disposed side by side in one direction.

The first contact electrode and the second contact electrode may be made of a conductive material constituting the anode.

The display device may further include a bank disposed over the planarization layer and extending to the non-display area, a part of the bank may constitute an island-shaped dummy bank at an edge of the non-display area, and the dummy bank may be disposed spaced apart from another part (e.g., a remaining part) of the bank.

The dummy bank may be disposed between the first contact electrode and the second contact electrode, and the dummy bank may be disposed in another direction perpendicular to the one direction.

The display device further includes an organic layer disposed on the bank, and may extend to the non-display area so that the edge of the organic layer is disposed inside compared to the edge of the bank.

A cathode disposed on the organic layer may be further included, and the cathode may extend to the non-display area to cover the organic layer and the bank.

A protective layer disposed on the cathode may be further included, and the protective layer may extend to the non-display area to cover the cathode.

The display device may further include an insulating layer disposed between the adhesive layer and the encapsulation substrate, the circuit part may be disposed at an edge of the non-display area in the adhesive layer between the substrate and the insulating layer.

The display device may further include a connector disposed over the substrate in the non-display area not covered by the encapsulation substrate, and a cable electrically connected to the connector.

The display device may further include a trench which is disposed in the non-display area and is formed by selectively removing a portion of the planarization layer, and the planarization layer may include an inner planarization layer disposed inside the trench with respect to the trench and an outer planarization layer disposed outside the trench.

The trench may be disposed in parallel with the dummy bank.

The display device may further includes an organic layer disposed on the bank, and may extend to the non-display area so that the edge of the organic layer is disposed inside compared to the edge of the bank.

A cathode disposed on the organic layer may be further included, and the cathode may extend to the non-display area to cover the organic layer, the bank, and the inner planarization layer.

The display device may further include a protective layer disposed on the cathode, the protective layer may extend into the trench to cover the cathode.

A display device according to another exemplary embodiment of the present disclosure may include a substrate including a display area and a non-display area outside the display area, a plurality of first link lines and a plurality of second link lines disposed over the substrate in the non-display area and separated from each other, a planarization layer extending from the display area to the non-display area, a sealing member disposed over the planarization layer and including a first adhesive layer and a second adhesive layer and a barrier layer disposed between the first adhesive layer and the second adhesive layer, a reinforcing substrate disposed on the second adhesive layer, a circuit part disposed within the first adhesive layer in the non-display area and having a driving IC disposed therein, a first connection part disposed between the plurality of first link lines and the circuit part, to electrically connect the plurality of first link lines with the circuit part, and a second connection part disposed between the plurality of second link lines and the circuit part, to electrically connect the plurality of second link lines with the circuit part.

The display device may further include an insulating layer disposed between the first adhesive layer and the barrier layer, and the circuit part may be disposed at an edge of the non-display area in the first adhesive layer between the substrate and the insulating layer.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area and a non-display;
a plurality of first link lines and a plurality of second link lines which are disposed over the substrate in the non-display area and are separated from each other;
a planarization layer extending from the display area to the non-display area;
an adhesive layer disposed over the planarization layer;
an encapsulation substrate disposed over the adhesive layer;
a circuit part disposed within the adhesive layer in the non-display area and having a driving IC disposed therein;
a first connection part disposed between the plurality of first link lines and the circuit part, to electrically connect the plurality of first link lines with the circuit part; and
a second connection part disposed between the plurality of second link lines and the circuit part, to electrically connect the plurality of second link lines with the circuit part.

2. The display device according to claim 1, further comprising:
a first contact hole and a second contact hole which are formed by removing a portion of the planarization layer of the non-display area to expose a portion of upper surfaces of one of the plurality of first link lines and one of the plurality of second link lines.

3. The display device according to claim 2, further comprising:
a first contact electrode disposed over the planarization layer and electrically connected to the one of the plurality of first link lines through the first contact hole; and
a second contact electrode disposed over the planarization layer and electrically connected to the one of the plurality of second link lines through the second contact hole,
wherein the first contact electrode and the second contact electrode are electrically connected to the first connection part and the second connection part, respectively.

4. The display device according to claim 2, further comprising a plurality of first contact electrodes and a plurality of second contact electrodes, and
wherein the plurality of first contact electrodes and the plurality of second contact electrodes respectively correspond to the plurality of first link lines and the plurality of second link lines.

5. The display device according to claim 3, wherein the first contact electrode and the second contact electrode overlap the first link line and the second link line, respectively, and
wherein the first contact electrode and the second contact electrode are disposed side by side in one direction.

6. The display device according to claim 3, further comprising a light emitting element having an anode, and
wherein the first contact electrode, the second contact electrode and the anode of the light emitting element includes a conductive material.

7. The display device according to claim 5, further comprising:
a bank disposed over the planarization layer and extending to the non-display area,
wherein a part of the bank includes an island-shaped dummy bank at an edge of the non-display area, and
wherein the dummy bank is disposed spaced apart from another part of the bank.

8. The display device according to claim 7, wherein the dummy bank is disposed between the first contact electrode and the second contact electrode.

9. The display device according to claim 1, further comprising:
an insulating layer disposed between the adhesive layer and the encapsulation substrate,
wherein the circuit part is disposed at an edge of the non-display area in the adhesive layer between the substrate and the insulating layer.

10. The display device according to claim 1, further comprising:
a connector disposed over the substrate in the non-display area not covered by the encapsulation substrate; and
a cable electrically connected to the connector.

11. The display device according to claim 7, further comprising:
a trench which is disposed in the non-display area and is formed by selectively removing a portion of the planarization layer,
wherein the planarization layer includes an inner planarization layer disposed inside the trench with respect to the trench, and an outer planarization layer disposed outside the trench and wherein the trench is disposed to be parallel to the dummy bank.

12. The display device according to claim 7, further comprising:
an organic layer disposed on the bank and extending to the non-display area so that an edge of the organic layer is disposed inside compared to an edge of the bank; and
a cathode disposed on the organic layer and extending to the non-display area to cover the organic layer and the bank.

13. A display device comprising:
a substrate including a display area and a non-display area;
a plurality of first link lines and a plurality of second link lines disposed over the substrate in the non-display area and separated from each other;
a planarization layer extending from the display area to the non-display area;
a sealing member disposed over the planarization layer and including a first adhesive layer and a second adhesive layer and a barrier layer disposed between the first adhesive layer and the second adhesive layer;
a reinforcing substrate disposed over the second adhesive layer;
a circuit part disposed within the first adhesive layer in the non-display area and having a driving IC disposed therein;
a first connection part disposed between the plurality of first link lines and the circuit part, to electrically connect the plurality of first link lines with the circuit part; and
a second connection part disposed between the plurality of second link lines and the circuit part, to electrically connect the plurality of second link lines with the circuit part.

14. The display device according to claim 13, further comprising:
an insulating layer disposed between the first adhesive layer and the barrier layer,
wherein the circuit part is disposed at an edge of the non-display area and in the first adhesive layer between the substrate and the insulating layer.

15. A display device comprising:
a substrate including a display area and a non-display area;
a plurality of first link lines and a plurality of second link lines which are disposed over the substrate in the non-display area and are separated from each other;
a planarization layer extending from the display area to the non-display area;
an encapsulation structure disposed over the planarization layer;
a circuit part disposed within the encapsulation structure in the non-display area and having a driving IC disposed therein;
a first connection part disposed between the plurality of first link lines and the circuit part, to electrically connect the plurality of first link lines with the circuit part; and
a second connection part disposed between the plurality of second link lines and the circuit part, to electrically connect the plurality of second link lines with the circuit part.

16. The display device according to claim 15, wherein the encapsulation structure includes a multilayer structure composed of a sealing member and a reinforcing substrate.

17. The display device according to claim 16, wherein the sealing member includes a first adhesive layer, a second adhesive layer, and a barrier layer disposed between the first adhesive layer and the second adhesive layer and the reinforcing substrate is disposed over the second adhesive layer.

18. The display device according to claim 17, wherein the first adhesive layer includes particles of an adhesive polymer material and a metal material.

19. The display device according to claim 17, wherein the first adhesive layer includes a hygroscopic inorganic filler.

20. The display device according to claim 17, wherein the circuit part is disposed in first adhesive layer.
